(19) United States
(12) Patent Application Publication
(10) Pub. No.: US 2008/0216957 A1
(43) Pub. Date: Sep. 11, 2008

(54) PLASMA PROCESSING APPARATUS, CLEANING METHOD THEREOF, CONTROL PROGRAM AND COMPUTER STORAGE MEDIUM

(75) Inventors: Kosuke Ogasawara, Nirasaki-shi (JP); Takamichi Kikuchi, Nirasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 12/040,222

(22) Filed: Feb. 29, 2008

Related U.S. Application Data
(60) Provisional application No. 60/938,713, filed on May 18, 2007.

(30) Foreign Application Priority Data
Mar. 8, 2007 (JP) 2007-058411

(51) Int. Cl. H01L 21/306; B08B 7/00

(52) U.S. Cl. 156/345.29; 134/1.1; 134/22.18; 438/905; 257/E21.226

(57) ABSTRACT

A cleaning method for a plasma processing apparatus includes introducing a cleaning gas containing Cl₂ and N₂ into the processing chamber by the gas supply mechanism; and removing aluminum-based deposits adhered to the inside of the processing chamber by generating a plasma of the cleaning gas by the plasma generating mechanism. The plasma processing apparatus includes a processing chamber for accommodating and processing a target substrate therein; a gas supply mechanism for supplying a gas into the processing chamber; a gas exhaust mechanism for evacuating the processing chamber; and a plasma generating mechanism for generating a plasma of the gas supplied in to the processing chamber.

### FIELD OF THE INVENTION

The present invention relates to a method for cleaning the inside of a processing chamber of a plasma processing apparatus which performs a plasma process such as an etching process or the like on a target substrate to be processed; and, more particularly, to a cleaning method for removing aluminum-based deposits inside a plasma processing apparatus, the plasma processing apparatus, and a control program and a computer-readable storage medium to be used therein.

### BACKGROUND OF THE INVENTION

Conventionally, a plasma processing apparatus such as a plasma etching apparatus is widely employed in, for example, a manufacturing process of fine electric circuits of a semiconductor device.

Recently, there has been proposed using a High-k film as an interlayer dielectric for a semiconductor device. Known as one kind of such high-k films is an Al₂O₃ film, and there is known a technique of etching the Al₂O₃ film by a plasma (see, for example, Patent Reference 1).

If the Al₂O₃ film is plasma etched, aluminum-based deposits would be adhered to the inside of a processing chamber of a plasma processing apparatus. To be used as a cleaning method for removing the aluminum-based deposits, there is known a method of using SF₆ or NF₃ as a cleaning gas and using a plasma of this cleaning gas. Further, as a cleaning method for cleaning the processing chamber after etching another type of High-k film, for example, HfO₂ or the like, there is known a method of using a plasma of, for example, a gaseous mixture of a halogen-based gas and either one of an oxygen-supplying gas and an oxidizing gas (see, for example, Patent Reference 2).

[Patent Reference 1]

Japanese Patent Laid-open Application No. 2004-296477

[Patent Reference 2]

Japanese Patent Laid-open Application No. 2006-179834

As described above, known as the conventional technique for removing the aluminum-based deposits is method of using the cleaning gas such as SF₆ or NF₃. However, this cleaning method is ineffective in removing the aluminum-based deposits, so that there has been a demand for the development of a highly effective cleaning method capable of removing the aluminum-based deposits sufficiently.

### SUMMARY OF THE INVENTION

In view of the foregoing, the present invention provides a highly effective cleaning method capable of removing aluminum-based deposits of a plasma processing apparatus efficiently; and, also, provides the plasma processing apparatus, and a control program and a computer-readable storage medium to be used therein.

In accordance with a first aspect of the present invention, there is provided a cleaning method for a plasma processing apparatus including a processing chamber for accommodating and processing a target substrate therein; a gas supply mechanism for supplying a gas into the processing chamber; a gas exhaust mechanism for evacuating the processing chamber; and a plasma generating mechanism for generating a plasma of the gas supplied in to the processing chamber. The method includes: introducing a cleaning gas containing Cl₂ and N₂ into the processing chamber by the gas supply mechanism; and removing aluminum-based deposits adhered to the inside of the processing chamber by generating a plasma of the cleaning gas by the plasma generating mechanism.

It is preferable that an inner pressure of the chamber is set to be about 0.1 Pa to 27 Pa.

The plasma generating mechanism may be configured to generate the plasma of the cleaning gas by applying a high frequency power of about 100 W to 3000 W between facing electrodes.

In accordance with a second aspect of the present invention, there is provided a plasma processing apparatus including: a processing chamber for accommodating and processing a target substrate therein; a gas supply mechanism for supplying a gas into the processing chamber; a gas exhaust mechanism for evacuating the processing chamber; a plasma generating mechanism for generating a plasma of the gas supplied into the processing chamber; and a control unit for performing a cleaning process by introducing a cleaning gas containing Cl₂ and N₂ into the processing chamber by means of the gas supply mechanism; and removing aluminum-based deposits adhered to the inside of the processing chamber by generating a plasma of the cleaning gas by means of the plasma generating mechanism.

In accordance with a third aspect of the present invention, there is provided a computer executable control program, which controls, when executed, a plasma processing apparatus to carry out the cleaning method disclosed above.

In accordance with a fourth aspect of the present invention, there is provided a computer readable storage medium which stores therein a computer executable control program, wherein, when executed, the control program controls a plasma processing apparatus to carry out the cleaning method disclosed above.

In accordance with the aspects of present invention, it is possible to provide a highly effective cleaning method capable of removing aluminum-based deposits of a plasma processing apparatus efficiently; and, also, provide a plasma processing apparatus, and a control program and a computer-readable storage medium to be used therein.

### BRIEF DESCRIPTION OF THE DRAWINGS

The above and other features of the present invention will become apparent from the following description of an embodiment given in conjunction with the accompanying drawings, in which:

FIG. 1 is a schematic configuration view of a plasma processing apparatus in accordance with an embodiment of the present invention;

FIG. 2 sets forth a chart providing comparison results of cleaning effects of various types of gases;

FIG. 3 presents a chart providing comparison results of cleaning effects under various cleaning conditions;

FIG. 4 provides a graph showing the results of FIG. 3 in a two-dimensional manner; and

FIG. 5 depicts a flow chart to describe a cleaning method for the plasma processing apparatus in accordance with the embodiment of the present invention.

### DETAILED DESCRIPTION OF THE EMBODIMENT

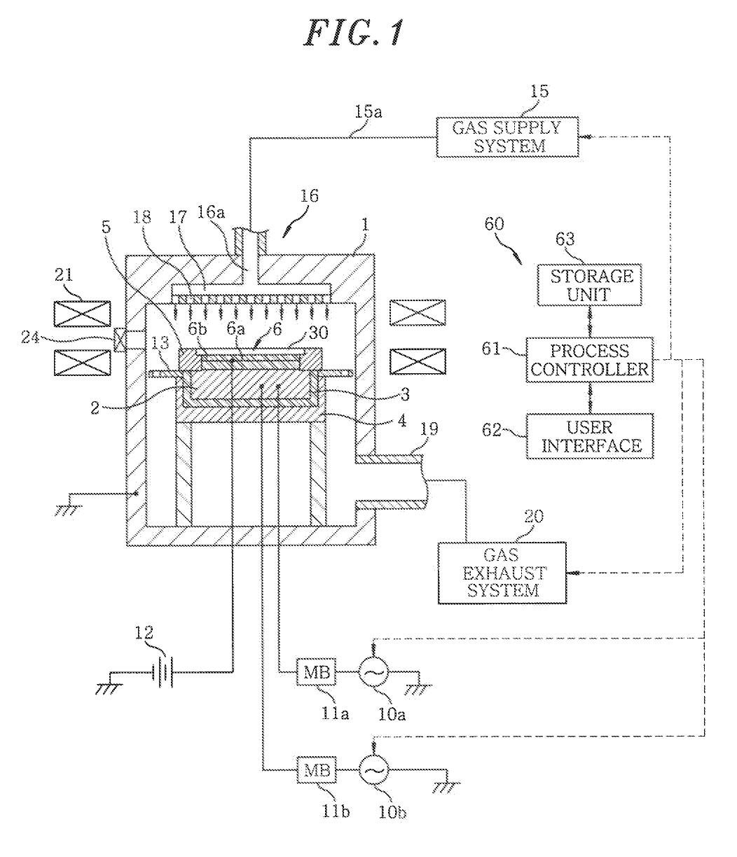

Hereinafter, an embodiment of the present invention will be described with reference to the accompanying drawings which form a part hereof. FIG. 1 illustrates a configuration of a plasma etching apparatus which is used as a plasma processing apparatus in accordance with the embodiment of the present invention. The plasma etching apparatus includes an air-tightly sealed processing chamber 1 which is electrically grounded.

The processing chamber 1 is of a cylindrical shape and is made of, for example, aluminum whose surface is coated with an anodic oxide film. Disposed inside the processing chamber 1 is a mounting table 2 for mounting thereon a semiconductor wafer 30 to be processed in a substantially horizontal manner. The mounting table 2 also serves as a lower electrode, and is made of a conductive material such as aluminum and supported on a conductive support 4 via an insulating plate 3. Further, an annular focus ring 5 is provided on a peripheral portion of a top surface of the mounting table 2 to surround the semiconductor wafer 30.

A first RF power supply 10a is connected to the mounting table 2 via first matching box (MB) 11a, and a second RF power supply 10b is also connected to the mounting table 2 via a second matching box (MB) 11b. A high frequency power of a specific frequency (for example, 100 MHz) is supplied to the mounting table 2 from the first RF power supply 10a, while a high frequency power of a specific frequency (for example, 13.56 MHz) lower than that from the first RF power supply 10a is supplied to the mounting table 2 from the second RF power supply 10b.

Meanwhile, a shower head 16 is disposed above the mounting table, while facing it in parallel. The shower head 16 is grounded. The shower head 16 and the mounting table 2 function as a pair of facing electrodes (an upper electrode and a lower electrode, respectively).

Disposed on the top surface of the mounting table 2 is an electrostatic chuck 6 for attracting and holding the semiconductor wafer 30 electrostatically. The electrostatic chuck 6 includes an electrode 6a embedded in an insulator 6b, and a DC power supply 12 is connected to the electrode 6a. By applying a DC voltage from the DC power supply 12 to the electrode 6a, the semiconductor wafer 30 is attracted to and held on the electrostatic chuck 6 by a Coulomb force.

Formed inside the mounting table 2 is a coolant path (not shown), and by circulating an appropriate coolant through the coolant path, the semiconductor wafer 30 can be regulated at a desired temperature degree. Further, a gas exhaust ring 13 is disposed outside the focus ring 5. The gas exhaust ring 13 is electrically connected to the processing chamber 1 via the support 4.

The shower head 16 is provided at a ceiling wall portion of the processing chamber 1, while facing the mounting table. The shower head 16 is provided with a number of gas injection openings 18 in its lower surface and a gas inlet 16a at its upper portion. The shower head 16 has a space 17 therein. One end of a gas supply line 15a is connected to the gas inlet 16a, and the other end of the gas supply line 15a is coupled to a gas supply system 15 for supplying a gas for plasma etching (etching gas) and a gas for cleaning (cleaning gas).

The gases supplied from the gas supply system 15 are introduced into the interior space 17 of the shower head 16 via the gas supply line 15a and the gas inlet 16a, and are discharged toward the semiconductor wafer 30 shown in FIG. 1 from the gas injection openings 18. In the present embodiment, the cleaning gas supplied from the gas supply system 15 is a gaseous mixture of Cl₂/N₂.

A gas exhaust port 19 is formed at a lower portion of the processing chamber 1, and a gas exhaust system 20 is connected to the gas exhaust port 19. By operating a vacuum pump provided in the gas exhaust system 20, the processing chamber 1 can be depressurized to a specific vacuum degree. Meanwhile, a gate valve 24 for opening or closing a loading/unloading port for the semiconductor wafer 30 is provided at a sidewall of the processing chamber 1.

Meanwhile, a ring magnet 21 is disposed concentrically around the processing chamber 1 to generate a magnetic field between the mounting table 2 and the shower head 16. The ring magnet 21 can be rotated by a rotation unit (not shown) such as a motor or the like.

The whole operation of the plasma etching apparatus configured as described above is controlled by a control unit 60. The control unit 60 functions as a CPU (central processing unit) and includes a process controller 61 for controlling individual constituent elements of the plasma etching apparatus; a user interface 62; and a storage unit 63.

The user interface 62 includes a key board for a process manager to input commands to operate the plasma etching apparatus, a display for visualizing an operational status of the plasma etching apparatus, and the like.

The storage unit 63 stores therein recipes including a control program (software), processing condition data and the like to be used in realizing various processes which are performed by the plasma etching apparatus under the control of the process controller 61. When a command is received from the user interface 62, a necessary recipe is retrieved from the storage unit 63 and executed by the process controller 61, whereby a desired process is performed by the plasma etching apparatus. Further, the recipes including the control program, the processing condition data and the like can be stored in a computer-readable storage medium (for example, a hard disk, a CD, a flexible disk, a semiconductor memory, or the like) or can be used on-line by being transmitted, when needed, from another apparatus, via, for example, a dedicated line.

Now, a process sequence of plasma-etching the semiconductor wafer 30, which is performed by the plasma etching apparatus configured as described above, will be explained. First, the gate valve 24 is opened, and the semiconductor wafer 30 is loaded into the processing chamber 1 by a transfer robot (not shown) or the like via a load lock chamber (not shown), and is mounted on the mounting table 2. Thereafter, the transfer robot is retreated from the processing chamber 1, and the gate valve 24 is closed. Then, the processing chamber 1 is evacuated by the vacuum pump of the gas exhaust system 20 via the gas exhaust port 19.

After the inside of the processing chamber 1 reaches a specific vacuum degree, an etching gas is introduced from the gas supply system 15 into the processing chamber 1, and the inside of the processing chamber 1 is maintained at a certain pressure level, for example, 8.0 Pa. In this state, high frequency powers are supplied from the first and second RF power supplies 10a and 10b to the mounting table 2. At this time, a specific DC voltage is applied from the DC power supply 12 to the electrode 6a of the electrostatic chuck 6, whereby the semiconductor wafer 30 is attracted to and held on the electrostatic chuck 6 by a Coulomb force or the like.

Here, as a result of the application of the high frequency powers to the mounting table 2 as described above, an electric field is formed between the shower head 16 serving as the upper electrode and the mounting table 2 serving as the lower electrode. Meanwhile, since a horizontal electric field is also formed between the shower head 16 and the mounting table 2 due to the presence of the ring magnet 21, electrons are made to drift, which in turn causes a generation of a magnetron discharge in a processing space in which the semiconductor wafer 30 is located. As a result of the magnetron discharge, a plasma of the processing gas is generated, and a High-k film such as an Al₂O₃ film formed on the semiconductor wafer 30 is etched by the plasma. At this time, aluminum-based deposits are accumulated on inner portions of the processing chamber 1.

Upon the completion of the etching process, the supply of the high frequency powers and the processing gas is stopped, and the semiconductor wafer 30 is unloaded from the processing chamber 1 in the reverse sequence as described above.

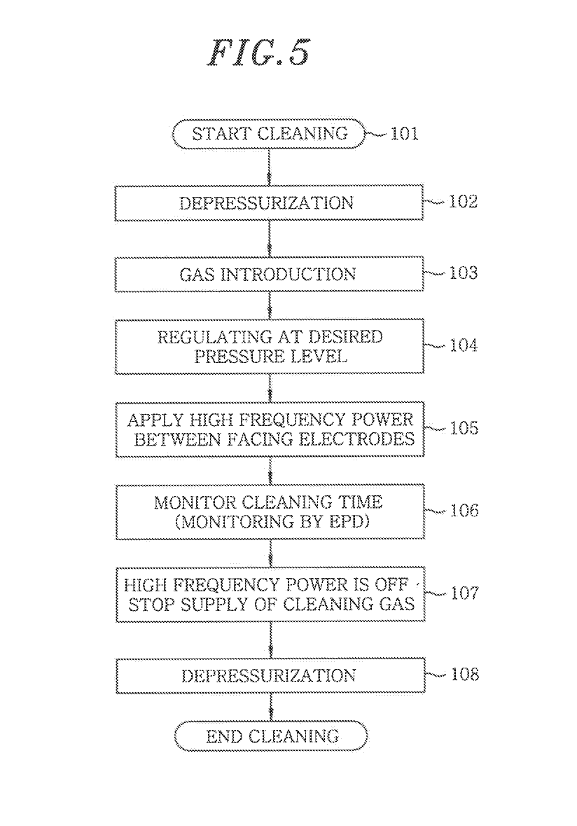

After the semiconductor wafer 30 is unloaded from the processing chamber 1, cleaning of the processing chamber 1, that is, removal of the aluminum-based deposits is carried out. This cleaning process is implemented by supplying a gaseous mixture containing Cl₂ and N₂, for example, a gaseous mixture of Cl₂/N₂ is supplied from the gas supply system 15 into the processing chamber 1 as a cleaning gas. The cleaning method will be described hereinafter with reference to FIG. 5. As for the cleaning method to be described below, a control program retrieved from the storage unit 63 of the control unit 60 is read by the process controller 61, and the process controller 61 controls each constituent component of the plasma etching apparatus based on the control program, whereby the cleaning method is conducted in accordance with the control program.

As shown in FIG. 5, if the cleaning is started (101), the processing chamber 1 is evacuated to vacuum by the gas exhaust system 20 so that the inside of the processing chamber 1 is regulated at a specific pressure level (for example, about 0.0013 Pa) (102).

Then, the cleaning gas (for example, the gaseous mixture of Cl₂/N₂) is introduced from the gas supply system 15 into the processing chamber 1 (103), and the inside of the processing chamber 1 is regulated at a desired pressure level (104).

Subsequently, a high frequency power of a specific frequency (for example, about 100 MHz) is supplied from the first RF power supply 10a to the mounting table 2 serving as the lower electrode, to thereby apply the high frequency power between the facing electrodes (105). As a result, a plasma of the cleaning gas is generated, and the removal of the aluminum-based deposits is carried out by the plasma. The high frequency power from the first RF power supply 10a may have a frequency range from, for example, about 100 W to 3000 W. At this time, no power is supplied from the second RF power supply 10b to prevent a damage upon the insulator 6b of the electrostatic chuck 6 by the plasma. Further, it is also possible to perform the cleaning process while protecting the insulator 6b by mounting a dummy wafer on the mounting table 2.

If the cleaning by the plasma is started, a cleaning time is monitored by an EPD (End Point Detector) (106). After the cleaning process is carried out for a preset time period, the application of the high frequency powers and the supply of the cleaning gas are stopped (107). Then, the processing chamber is evacuated to vacuum by the gas exhaust system 20 so that its inner pressure is regulated at a specific pressure level (for example, 0.0013 Pa) (108).

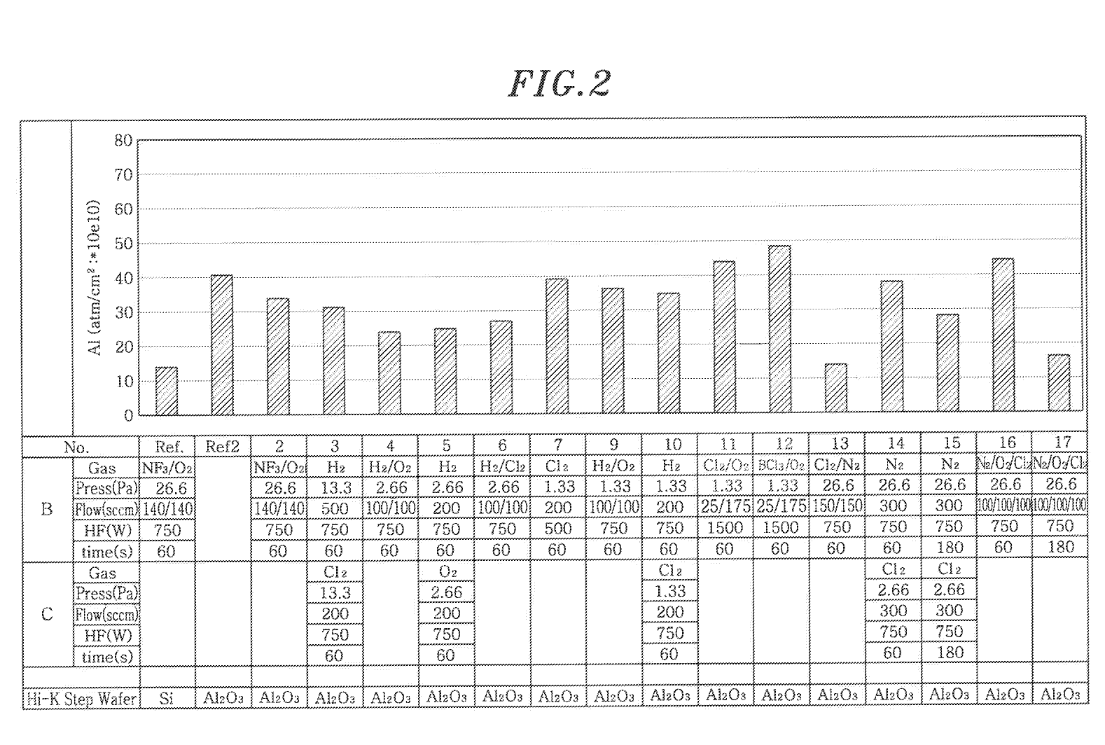

Now, the reason for using the gaseous mixture of Cl₂/N₂ as the cleaning gas in the present embodiment will be explained. FIG. 2 shows inspection results of cleaning effects of various types of cleanings gases upon aluminum-based deposits. That is, FIG. 2 provides measurement results of an amount of aluminum contaminants in the processing chamber after the cleaning process is performed upon the completion of the etching of the Al₂O₃ film formed on the semiconductor wafer 30.

A vertical axis of the bar graph of FIG. 2 represents an aluminum amount (atm/cm²). Further, in FIG. 2, Reference (Ref) shows a measurement result (aluminum amount=14×10¹⁰ atm/cm², unit being omitted hereinafter) when a cleaning process is performed with a NF₃/O₂ gas (140/140 sccm) at a power of 750 W under a pressure of 26.6 Pa for 60 seconds. Further, Reference 2 (Ref2) shows a measurement result (aluminum amount=41) obtained after etching the Al₂O₃ without performing a cleaning process. Accordingly, in analyzing other measurement results, an aluminum amount would become closer to the value (41) of Ref 2 if a cleaning effect is low, while the aluminum amount would become closer to the value (14) of Ref in the event that a cleaning effect is high so that the aluminum-based deposits are almost completely removed.

Further, cleaning conditions and measurement results of Examples Nos. 2 to 7 and 9 to 17 in FIG. 2 are as follows:

### Example No. 2

NF₃/O₂=140/140 sccm, pressure=26.6 Pa, power=750 W, time=60 seconds, aluminum amount=34;

### Example No. 3

H₂=500 sccm, pressure=13.3 Pa, power=750 W, time=60 seconds/Cl₂=200 sccm, pressure 13.3 Pa, power=750 W, time=60 seconds, aluminum amount=31;

### Example No. 4

H₂/O₂=100/100 sccm, pressure=2.66 Pa, power=750 W, time=60 seconds, aluminum amount=24;

### Example No. 5

H₂=200 sccm, pressure=2.66 Pa, power=750 W, time=60 seconds/O₂=200 sccm, pressure=2.66 Pa, power=750 W, time=60 seconds, aluminum amount=27;

### Example No. 6

H₂/Cl₂=100/100 sccm, pressure=2.66 Pa, power=750 W, time=60 seconds, aluminum amount=27;

### Example No. 7

Cl₂=200 scam, pressure=1.33 Pa, power=500 W, time=60 seconds, aluminum amount=39;

### Example No. 9

H₂/O₂=100/100 sccm, pressure=1.33 Pa, power=750 W, time=60 seconds, aluminum amount=36;

### Example No. 10

H₂=200 sccm, pressure=1.33 Pa, power=750 W, time=60 seconds/Cl₂=200 sccm, pressure=1.33 Pa, power=750 W, time=60 seconds, aluminum amount=35;

### Example No. 11

Cl₂/O₂=25/175 sccm, pressure=1.33 Pa, power=1500 W, time=60 seconds, aluminum amount=44;

### Example No. 12

BCl₃/O₂=25/175 sccm, pressure=1.33 Pa, power=1500 W, time=60 seconds, aluminum amount=48;

### Example No. 13

Cl₂/N₂=150/150 sccm, pressure=26.6 Pa, power=750 W, time=60 seconds, aluminum amount=14;

### Example No. 14

N₂=300 scam, pressure=26.6 Pa, power=750 W, time=60 seconds/Cl₂=300 sccm, pressure=26.6 Pa, power=750 W, time=60 seconds, aluminum amount=38;

### Example No. 15

N₂=300 sccm, pressure=26.6 Pa, power=750 W, time=180 seconds/Cl₂=300 sccm, pressure=26.6 Pa, power=750 W, time=180 seconds, aluminum amount=28;

### Example No. 16

N₂/O₂/Cl₂=100/100/100 sccm, pressure=26.6 Pa, power=750 W, time=60 seconds, aluminum amount=44;

### Example No. 17

N₂/O₂/Cl₂=100/100/100 sccm, pressure=26.6 Pa, power=750 W, time=180 seconds, aluminum amount=16.

As revealed in Table 2, the aluminum amount of the Example No. 13 in which the gaseous mixture of Cl₂/N₂ was used is lower than those of the other examples where other types of cleaning gases are employed, so a cleaning effect of that cleaning gas is found to be very high. Further, in case of the Example No. 13, the aluminum amount is 14, which is almost the same level as that of Ref in which no etching of Al₂O₃ film is performed.

Furthermore, in the Example No. 17 in which the gaseous mixture containing Cl₂ and N₂, i.e., N₂/O₂/Cl₂, is used, the aluminum amount is also found to be reduced in comparison with the other examples where other types of cleaning gases are employed, so a cleaning effect of that cleaning gas is also deemed to be high. In comparison of the Example No. 17 with the Example No. 13, the cleaning time of the Example No. 17 is 180 seconds longer than that of the Example No. 13, though its aluminum amount is 16 greater than that of the Example No. 13. From this comparison, it can be concluded that it is more preferable to use, as a cleaning gas, the gaseous mixture of Cl₂/N₂ which dose not contain O₂. Moreover, some of the Examples show aluminum amounts greater than that of Ref2 and are thus deemed to have substantially no cleaning effects. Such apparent aluminum amounts up to a level higher than that of the case of performing no cleaning process seems to be due to experiment deviations or measurement errors.

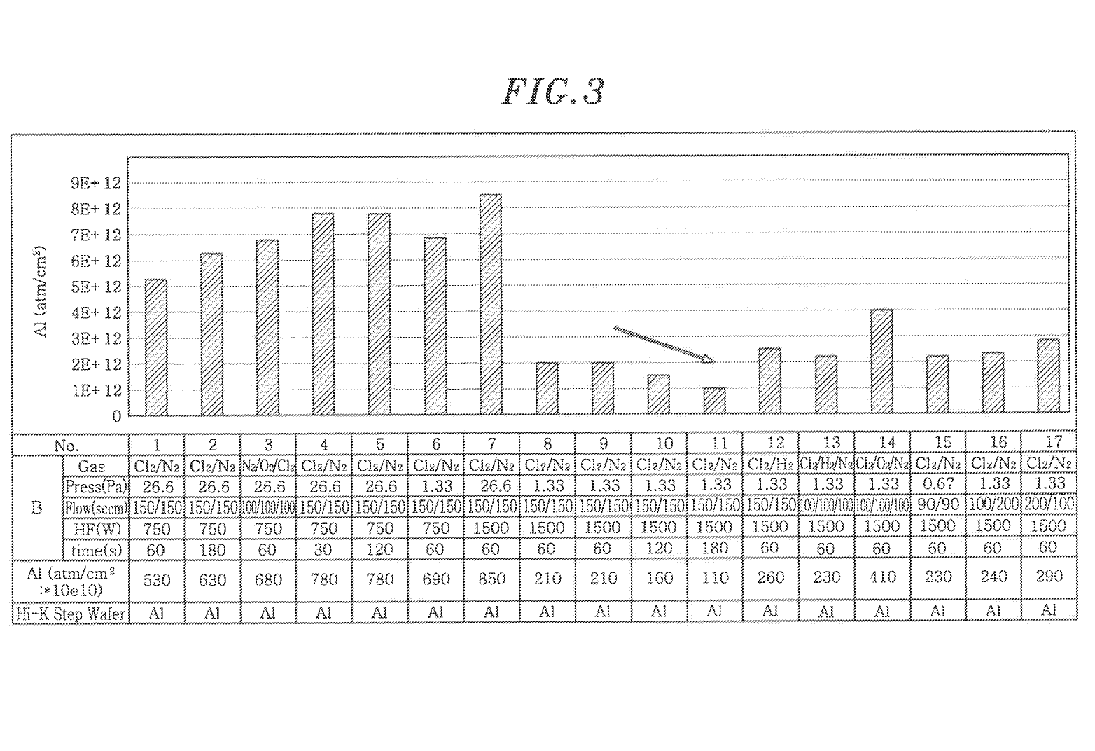

FIG. 3 shows inspection results of various cleaning conditions suitable for using the cleaning gas containing Cl₂ and N₂. FIG. 3 provides measurement results of an amount of aluminum contaminants in the processing chamber after the cleaning process is performed upon the completion of the etching of Al. The gaseous mixture of Cl₂/H₂ not containing N₂ gas is used only in the example No. 12. A vertical axis of the bar graph of FIG. 3 represents an aluminum amount (atm/cm²).

Cleaning conditions and measurement results of Examples Nos. 1 to 17 in FIG. 3 are as follows:

### Example No. 1

Cl₂/N₂=150/150 sccm, pressure=26.6 Pa, power=750 W, time=60 seconds, aluminum amount=530;

### Example No. 2

Cl₂/N₂=150/150 sccm, pressure=26.6 Pa, power=750 W, time=180 seconds, aluminum amount=630;

### Example No. 3

N₂/O₂/Cl₂=100/100/100 sccm, pressure=26.6 Pa, power=750 W, time=60 seconds, aluminum amount=680;

### Example No. 4

Cl₂/N₂=150/150 sccm, pressure=26.6 Pa, power=750 W, time=30 seconds, aluminum amount=780;

### Example No. 5

Cl₂/N₂=150/150 sccm, pressure=26.6 Pa, power=750 W, time=120 seconds, aluminum amount=780;

### Example No. 6

Cl₂/N₂=150/150 sccm, pressure=1.33 Pa, power=750 W, time=60 seconds, aluminum amount=690;

### Example No. 7

Cl₂/N₂=150/150 sccm, pressure=26.6 Pa, power=1500 W, time=60 seconds, aluminum amount=850;

### Example No. 8

Cl₂/N₂=150/150 sccm, pressure=1.33 Pa, power=1500 W, time=60 seconds, aluminum amount=210;

### Example No. 9

Cl₂/N₂=150/150 sccm, pressure=1.33 Pa, power=1500 W, time=60 seconds, aluminum amount=210;

### Example No. 10

Cl₂/N₂=150/150 sccm, pressure=1.33 Pa, power=1500 W, time=120 seconds, aluminum amount=160;

### Example No. 11

Cl₂/N₂=150/150 sccm, pressure=1.33 Pa, power=1500 W, time=180 seconds, aluminum amount=110;

### Example No. 12

Cl₂/H₂=150/150 sccm, pressure=1.33 Pa, power=1500 W, time=60 seconds, aluminum amount=260;

### Example No. 13

Cl₂/H₂/N₂=100/100/100 sccm, pressure=1.33 Pa, power=1500 W, time=60 seconds, aluminum amount=230;

### Example No. 14

Cl₂/O₂/N₂=100/100/100 sccm, pressure=1.33 Pa, power=1500 W, time=60 seconds, aluminum amount=410;

### Example No. 15

Cl₂/N₂=90/90 sccm, pressure=0.67 Pa, power=1500 W, time=60 seconds, aluminum amount=230;

### Example No. 16

Cl₂/N₂=100/200 sccm, pressure=1.33 Pa, power=1500 W, time=60 seconds, aluminum amount=240;

### Example No. 17

Cl₂/N₂=200/100 sccm, pressure=1.33 Pa, power=1500 W, time=60 seconds, aluminum amount=290.

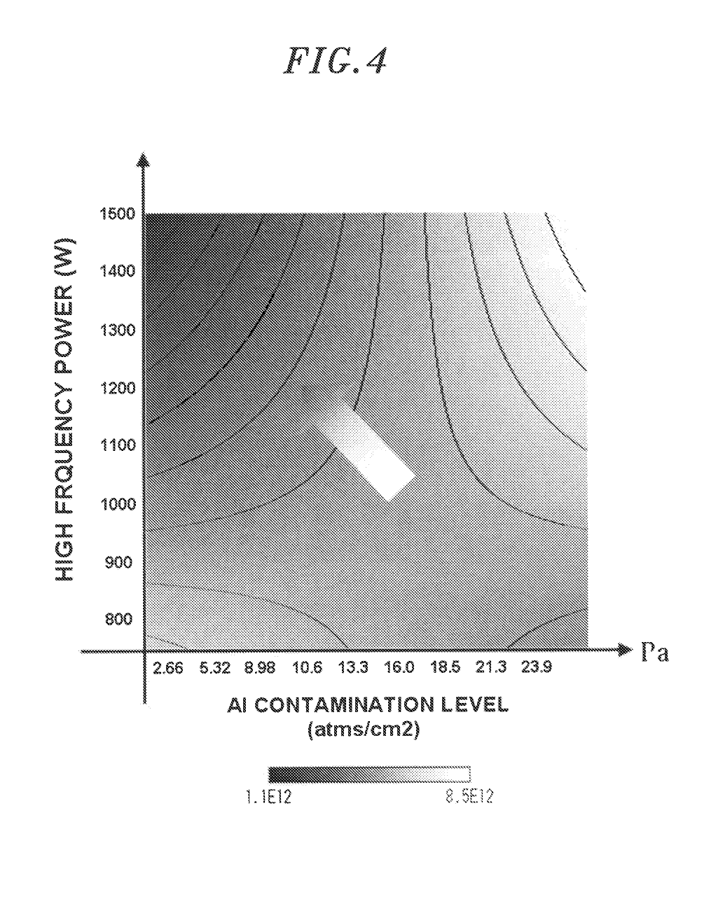

FIG. 4 provides the above-specified measurement results of aluminum amounts in a graph of which vertical axis is a high frequency power (W) and horizontal axis is a pressure (Pa), by using shades (a darker portion indicates a smaller aluminum amount) and contour lines. As shown in FIG. 4, in case a pressure is low but a high frequency power is high, an aluminum amount is small and thus a cleaning effect is high.

In FIG. 3, the Example Nos. 1 to 5 are cases in each of which the pressure is 26.6 Pa and the high frequency powers is 750 W, and Example Nos. 8 to 17 are cases in each of which the pressure is 1.33 Pa or lower and the high frequency power is 1500 W. The tendency described in FIG. 4 is also found from the analysis of the measurement results of these examples. Further, the Example No. 6 is a case in which the pressure is 1.33 Pa and the high frequency power is 750 W, and the Example No. 7 is a case in which the pressure is 26.6 Pa and the high frequency power is 1500 W. From the analysis of the measurement results of these examples, it can be seen that a cleaning effect hardly improves by only decreasing the pressure or increasing the high frequency power, but can be achieved by means of decreasing the pressure while increasing the high frequency power at the same time.

Accordingly, it is preferable to set the high frequency power to be no smaller than 1000 W. Given that a general upper limit for a high frequency power of a plasma etching apparatus is about 3000 W, a preferable range for the high frequency power for the cleaning process may be about 1000 to 3000 W. Further, it is preferable to set the pressure to be no greater than 27 Pa and, more preferably, to be lower than about 10 Pa while setting a lower limit to be about 0.1 Pa. Thus, the pressure is preferably determined in the range of about 0.1 Pa to 27.0 Pa and, more preferably, in the range of about 0.1 Pa to 10.0 Pa.

Further, the Example Nos. 15 to 17 provide variation results of a flow rate ratio between Cl₂ and N₂ gases. As reveled from FIG. 3, though the flow rate ratio of these gases dose not have a considerable influence upon the cleaning state, it is preferable to set it to be about 1:1. Moreover, though a flow rate of each gas can be determined in the range of about 10 sccm to 1000 sccm, it is preferable to set them in the range of about 100 scam to 200 sccm. In addition, the Examples Nos. 9 to 11 are obtained under the same cleaning conditions while varying a cleaning time only. As revealed from the analysis of these examples, though a cleaning effect improves as the cleaning time is lengthened, it is preferable to determine the cleaning time in the range of, for example, about 30 to 300 seconds.

Here, it is to be noted that the present invention is not limited to the above-described embodiment but can be modified in various ways. For example, the plasma etching apparatus is not limited to the parallel plate type apparatus which applies dual frequency powers to the lower electrode, but it can be of a type which applies respective high frequency powers to the upper and lower electrodes, or a type which applies dual frequency powers to the upper electrode, and the like.

While the invention has been shown and described with respect to the embodiment, it will be understood by those skilled in the art that various changes and modifications may be made without departing from the scope of the invention as defined in the following claims.

What is claimed is:

1. A cleaning method for a plasma processing apparatus including a processing chamber for accommodating and processing a target substrate therein; a gas supply mechanism for supplying a gas into the processing chamber; a gas exhaust mechanism for evacuating the processing chamber; and a plasma generating mechanism for generating a plasma of the gas supplied in to the processing chamber, the method comprising:
introducing a cleaning gas containing Cl₂ and N₂ into the processing chamber by the gas supply mechanism; and
removing aluminum-based deposits adhered to the inside of the processing chamber by generating a plasma of the cleaning gas by the plasma generating mechanism.

2. The cleaning method of claim 1, wherein an inner pressure of the chamber is set to be about 0.1 Pa to 27 Pa.

3. The cleaning method of claim 1, wherein the plasma generating mechanism is configured to generate the plasma of the cleaning gas by applying a high frequency power of about 100 W to 3000 W between facing electrodes.

4. A plasma processing apparatus comprising:
a processing chamber for accommodating and processing a target substrate therein;
a gas supply mechanism for supplying a gas into the processing chamber;
a gas exhaust mechanism for evacuating the processing chamber;
a plasma generating mechanism for generating a plasma of the gas supplied into the processing chamber; and
a control unit for performing a cleaning process by introducing a cleaning gas containing Cl₂ and N₂ into the processing chamber by means of the gas supply mechanism; and removing aluminum-based deposits adhered to the inside of the processing chamber by generating a plasma of the cleaning gas by means of the plasma generating mechanism.

5. A computer executable control program, which controls, when executed, a plasma processing apparatus to carry out the cleaning method disclosed in claim 1.

6. A computer readable storage medium which stores therein a computer executable control program, wherein, when executed, the control program controls a plasma processing apparatus to carry out the cleaning method disclosed in claim 1.
